(19) United States
(12) Patent Application Publication
(10) Pub. No.: US 2004/0152268 A1
(43) Pub. Date: Aug. 5, 2004

(54) Novel method of fabricating split gate flash memory cell without select gate-to-drain bridging

(75) Inventors: Kwo Wei Chu, Taipei (TW); Chih Ming Chen, Hsinchu (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Company

(21) Appl. No.: 10/358,655

(22) Filed: Feb. 5, 2003

(51) Int. Cl. H01L 21/336

(52) U.S. Cl. 438/266; 438/258; 438/257

(57) ABSTRACT

A method of forming triple poly silicon split gate flash memory cell comprising of select gate, floating gate, and control gate having the three poly-silicon gates fully aligned with each other is described. High-resolution select-gate poly-silicon-1 is patterned using I-line lithography and resist instead of deep UV (DUV) lithography resist, as is normally used in prior art, which reduces cost of fabrication. Further, the triple poly-silicon structure is etched in a self-aligned manner and also provided with dielectric spacers in the source and drain contact regions prior to forming silicided metal contacts. Self-aligned etching in conjunction with dielectric spacers provide electrical isolation on the drain side and prevent potential bridging between select-gate poly silicon-1 and the drain.

### BACKGROUND OF THE INVENTION

(I) Field of the Invention

The present invention relates generally to method of fabricating a triple-poly split gate flash memory cell, and more particularly, to fabricate the split gate cell provided with isolation spacers in such a way as to prevent bridging between select gate and drain region of an FET device.

(2) Description of the Prior Art

High-density flash memories are being increasingly used in still cameras and hand-held devices like cell phones and palm-held computers. In these miniaturized applications, memory cell size needs to be kept as small as economically feasible. Smaller cell size implies higher number of chips per wafer with resulting increase in productivity and decreased cost at the same time increasing the speed of the device. Formation of source and drain electrical contacts, while allowing adequate spacing from the gate conductor, can take up significant real estate from the cell size, thereby making the overall memory cell larger. Achievable source/drain-to-gate distance depends on several factors such as alignment accuracy of the litho tools and process control of etching tools. To overcome this problem, many self-aligned contact schemes have been proposed in the prior art.

U.S. Pat. No. 5,668,757 describes a triple-poly EEPROM (electrically erasable and programmable read only memory) cell with source drain, and a channel in between. A select gate is placed over a portion of the channel and is insulated therefrom. A floating gate has a first portion over the select gate insulated therefrom and a second portion over a second portion of the channel and over the source and is located in between the select gate and the source. A control gate is over the floating gate and insulated therefrom. A memory array using this cell is also disclosed.

U.S. Pat. No. 6,232,185B1 describes methods of forming three types of nonvolatile memory cells, having a select gate, a floating gate, and a control gate, using self-aligned, partially-aligned, and non-self-aligned schemes. Each of the three types of cells has a floating gate whose linear dimension can be increased beyond the limits of the lithographic process. The self-aligned cell comprises the steps of forming an active region between two isolation regions in the silicon substrate. After first forming the insulating film on the substrate, first poly-silicon layer is deposited on the insulating film followed by the deposition of a second insulating film over the first poly-silicon layer. The second insulating film and the first poly-silicon layer are etched such that a portion of the etched poly-silicon layer lies over the channel region. A second poly-silicon layer is then deposited over the first and second insulating films. A plurality of sacrificial masking film strips are formed on the second poly-silicon layer, with each strip positioned over an active region and between a pair of isolation regions. The second poly-silicon layer is then etched using the said sacrificial masking strips. A third insulating film is then deposited over the second poly-silicon layer and a third poly-silicon layer over this insulating film. The third poly-silicon layer is etched to form the control gate and this control gate in turn is used to etch the first and second poly-silicon layers to form the select and floating gates.

U.S. Pat. No. 6,246,612B1 discloses a low-voltage method of erasing and low-voltage programming a non-volatile memory cell that comprises a source and drain region and a channel there-between, a floating gate extending over a portion of the said channel, a control gate partially positioned over the channel region, and a program gate capacitively coupled through a dielectric layer to said floating gate.

### SUMMARY OF TUE INVENTION

Accordingly, one objective of the invention is to describe a method to form a triple poly-silicon split gate flash memory cell without select gate-to-drain bridging.

It is yet another objective to describe a method of forming a triple poly-silicon memory cell using I-line lithography to form the select poly-silicon gate.

It is also another objective to describe a method to form the electrical contacts with high temperature oxide spacers and self-aligned etching.

It is yet another objective to describe a triple poly-silicon gate field effect transistor (FET) structure for flash memory cell, with spacers in the source/drain contact regions.

In the present invention, a method is described of forming a flash memory cell by using a low-resolution I-line lithography to define the select gate poly-I and later split the select gate using self-aligned anisotropic plasma etching of floating gate (poly silicon-1) and select gate (poly silicon-2). High temperature oxide (HTO) spacer is then formed after all the implantation steps and prior to defining the silicided electrical contacts, with the HTO spacers thereby preventing select gate-to-drain bridging. Two mirror image cells are thus formed, with a common drain contact and with each select gate in each of the two cells being of smaller dimension than it was originally defined in the I-line resist.

### BRIEF DESCRIPTION OF THE DRAWINGS

FIG. 1 is a cross-sectional view of select gate poly silicon-1 structure (patterned by using I-line lithography), showing the silicon substrate, select gate oxide, gate poly silicon-1, and first high temperature oxide (HTO) on top of poly silicon-1.

FIG. 2 is a cross-sectional view of the select gate after forming the HTO spacer around the select gate structure.

FIG. 3 is a cross-sectional view of the partial cell structure, showing select gate poly silicon-1, floating gate oxide, floating gate poly-2, and oxide-nitride-oxide (ONO) films.

FIG. 4 is a cross-sectional view of the partial cell structure, showing select gate, floating gate, and control gate poly silicon-3 with silicon oxy-nitride (SiON) on top of poly silicon-3.

FIG. 5 is a cross-sectional view of the partial cell structure (showing said three gate structures), with resist mask pattern and poly silicon-3 gate selectively etched to stop on the ONO layer.

FIG. 6 is a cross-sectional view of two complete mirror image cells after self-aligned etching of gate poly silicon-2, stopping on HTO; and after self-aligned etching of gate poly silicon-1, stopping on select gate oxide.

FIG. 7 is a cross-sectional view of two mirror image cells, showing source and drain regions formed by ion implantation of dopants.

FIG. 8 is a cross-sectional view of two mirror image cells, showing HTO isolation spacers and silicided electrical contacts.

### DETAILED DESCRIPTION OF THE INVENTION

Process flow of forming twin flash memory cell using split gate architecture according to the preferred embodiment of the invention is described in detail. The vertical scale is exaggerated in the accompanying drawings to more clearly illustrate the embodiment of the invention.

FIG. 1 is a cross-sectional view of the partially fabricated cell structure, wherein on a silicon substrate 10, select-gate silicon dioxide 20 is thermally grown, select-gate poly silicon-1 (P1) layer 21 is then deposited using methods known in the prior art, followed by first high temperature oxide 22 (HTO) deposition at 790° C., using methods known in the prior art. The select-gate stack of silicon dioxide, poly silicon-1, and HTO is then patterned using I-line lithography and selective plasma etching process known in prior art and the resist mask is stripped.

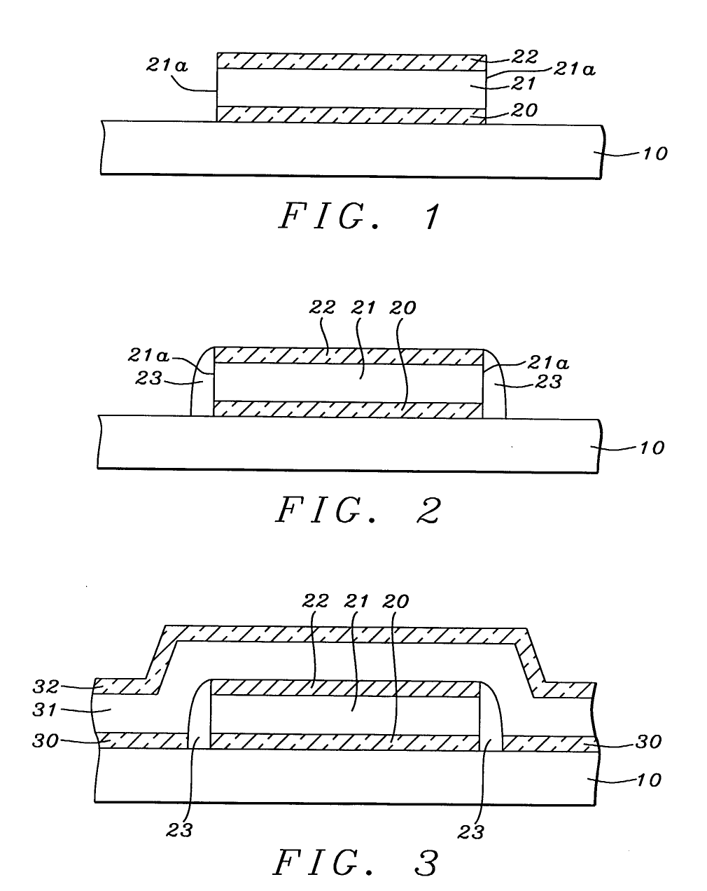

A layer of second HTO is then deposited conformally at 790° C. over the structure of FIG. 1 and the HTO film anisotropically etched using a plasma process known in the prior art, such that said second HTO film on all horizontal surfaces is etched, forming the first silicon dioxide spacers 23 on the sidewalls 21a of the select-gate structure. The resulting gate structure is shown in FIG. 2.

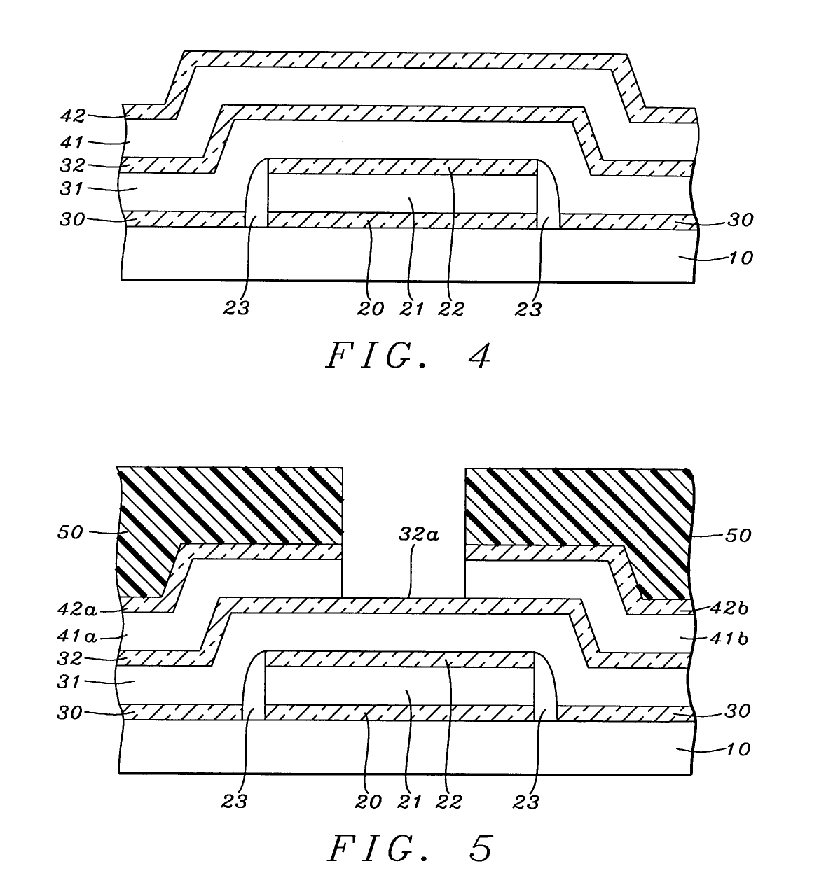

Floating-gate oxide 30 is then deposited on the gate structure shown in FIG. 2 using a process known in the prior art, followed by floating-gate poly silicon-2 (P2) layer 31 (using a process described earlier for poly silicon-1 film 21), and oxide-nitride-oxide (ONO) film 32 using a process known in the prior art. All the deposition processes used here are known in the art. The resulting cell structure with select-gate poly silicon 21 and floating-gate poly silicon 31 is shown in FIG. 3.

FIG. 4 is a cross-sectional view of the partial cell structure after depositing control-gate poly silicon-3 (P3) layer 41 (using similar process as for poly silicon-1 film 21) and silicon oxy-nitride (SiON) film 42 on the cell structure of FIG. 3, using processes known in the prior art.

A resist mask 50 is then formed on the structure shown in FIG. 4, aligning the mask to the active area on substrate 10 and using standard lithographic methods. The SiON film 42 is etched anisotropically with a plasma process known in the prior art, followed by selective anisotropic etching of poly silicon-3 film 41 with a process known in the prior art such that etching stops on the surface 32a of the ONO film 32. Films 41 and 42 (FIG. 4) are split at this step into 41a, 41b and 42a, 42b. The resulting cell structure is shown in FIG. 5.

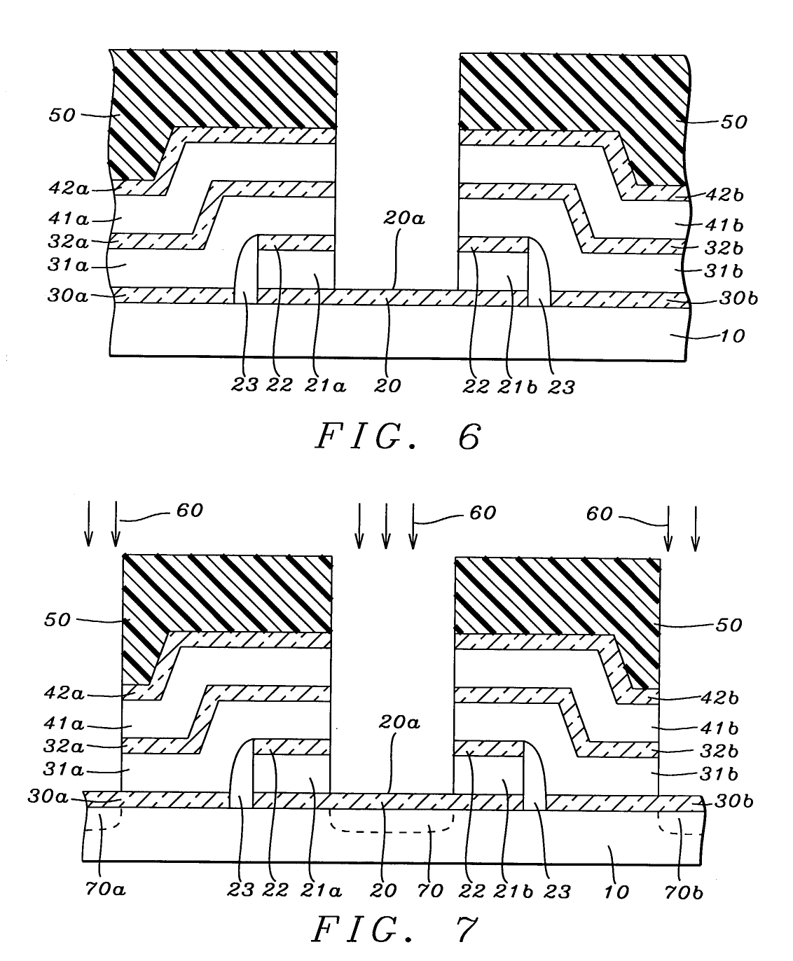

Self-aligned etching of film 32 is performed next, using a process known in the prior art, followed by selective etching of poly silicon-2 film 31 (with the process described earlier for etching film 21) to stop on first HTO film 22. Another self-aligned etching of the first HTO film 22 is performed next with process known in the prior art, followed by selective etching of poly silicon-1 film 21 (using similar process as for etching film 21) to stop on select gate silicon dioxide 20. The resulting structure, with split poly silicon gates 21a, 21b, 31a, 31b and 41a, 41b and split floating gate oxide, 30a, 30b, is shown in FIG. 6.

With resist mask still in place, source 70a and drain 70b regions are formed in substrate 10 by doping these regions with ion implantation techniques known in the prior art. The cell structure with implanted source and drain regions is shown in FIG. 7.

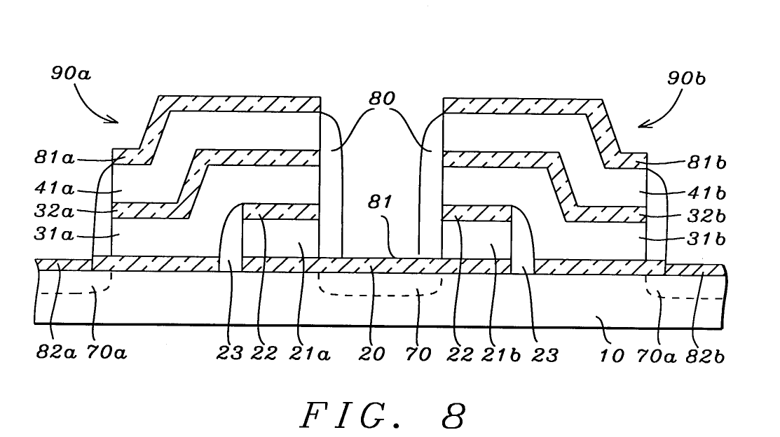

Second HTO spacers 80, as shown in FIG. 8, are then formed using the methods, known in the prior art, that of depositing silicon dioxide conformally and anisotropic etching of said dioxide at which time the silicon surface gets exposed in all the contact regions. Said HTO spacer is critical in preventing potential bridging or shorting between select-gate poly silicon-1 21a or 21b and the drain 70. Bridging to source region is not likely due to cell design, since poly silion-1 21a and 21b are far removed from source region 70a or 70b. Although silicon dioxide is used for spacers in the preferred embodiment, other dielectric films to include silicon nitride, silicon oxy-nitride, or nitrided oxide, can be substituted. Contact metal, titanium, is then deposited and annealed to form sicides on exposed silicon surfaces. Un-reacted titanium on dioxide surfaces, including spacers, is then removed by wet etching. Although titanium is preferably used as the contact metal, other suitable metals can be substituted. The alternate metals include: cobalt, tantalum, or nickel. The self-aligned silicided (or salicide) contact regions 81, 81a and 81b, 82a and 82b are shown in FIG. 8, which also shows the two mirror image twin cells 90a and 90b with higher resolution poly silicon-1 select gates 21a and 21b formed from the original select gate structure 21 shown in FIG. 1. Also shown in FIG. 8 are the floating gates 31a and 31b and control gates 41a and 41b. FIG. 8 also shows the spacers 80 which prevent bridging between select gates 21a and 21b to drain 70.

The advantages of this invention over prior art are:

a) Select gate poly silicon-1 is formed by using I-line resist mask and litho process, instead of deep UV resist used in the prior art. This choice reduces the cost of fabrication, DUV litho system being much more expensive than the I-line system.

b) Use of high temperature oxide spacers, that define silicided drain contact regions, combined with self-aligned etching of poly silicon gates to form vertical gate sidewalls, prevent select gate-to-drain bridging,

c) Increased coupling ratio due to increased floating gate and control gate surface area, which in turn increases the capacitance of the control gate dielectric layer (e.g. ONO),

d) The invention structure keeps all the advantages of split gate flash memory cell.

While the invention has been particularly shown and described with reference to the preferred embodiment thereof, it will be understood by those skilled in the art that various changes in form and details may be made without departing from the concept, spirit, and the scope of the invention.

What is claimed is:

1. A method of forming select gate for a split gate flash memory cell comprising:
forming a poly silicon select gate stack on a silicon substrate, said stack including select gate oxide, select gate poly silicon layer, and high temperature oxide (HTO) film;
forming select gate mask on said select gate stack; and
selective etching of said select gate stack to stop on said substrate.

2. A method of forming split gate flash memory cell according to claim 1, wherein said selective gate oxide thickness is between about 50-80° A.

3. A method of forming split gate flash memory cell according to claim 1, wherein said gate poly silicon-1 thickness is between about 1000-1500° A.

4. A method of forming a split gate flash memory cell without bridging between select gate and drain, comprising:
forming a poly silicon-1 select gate stack on a silicon substrate, said stack including gate oxide, a gate poly silicon-1 layer, and first high temperature oxide (HTO) film;
etching said select gate stack;
forming sidewall silicon oxide spacers around said poly silicon-1 etched structure, depositing floating gate oxide, floating gate poly silicon-2, and oxide/nitride/oxide (ONO) films over said select gate poly silicon-1 etched structure;
depositing control gate poly silicon-3 and silicon-oxy-nitride (SiON) films over said poly-silicon-1/poly-silicon-2 composite structure;
selective anisotropic etching of said SiON and poly-silicon-3 films to stop on said ONO film;
forming two mirror image gate structures by two-step etching of said ONO and poly silicon-2 films to stop on said HTO film and then etching of said HTO and poly silicon-1 films to stop on said select gate oxide;
forming source and drain regions;
forming dielectric spacers in the drain contact region; and
forming electrical contacts on said silicon surfaces.

5. A method of forming split gate flash memory cell according to claim 4, wherein said selective gate oxide thickness is between about 50-80° A.

6. A method of forming split gate flash memory cell according to claim 4, wherein said gate poly silicon-1 thickness is between about 1000-1500° A.

7. A method of forming split gate flash memory cell according to claim 4, wherein said first high temperature oxide thickness is between about 700-1000° A.

8. A method of forming split gate flash memory cell according to claim 4, wherein said floating gate oxide thickness is between about 70-110° A.

9. A method of forming split gate flash memory cell according to claim 4, wherein said select gate stack is etched using I-line resist mask.

10. A method of forming split gate flash memory cell according to claim 4, wherein said gate poly silicon-2 thickness is between about 800-1200° A.

11. A method of forming split gate flash memory cell according to claim 4, wherein said ONO film thickness is between about 40-80° A for bottom silicon oxide, about 60-100° A for silicon nitride, and about 40-80° A for top silicon oxide.

12. A method of forming split gate flash memory cell according to claim 4, wherein said gate poly silicon-3 film thickness is between about 2000-3000° A.

13. A method of forming split gate flash memory cell according to claim 4, wherein said silicon oxy nitride film thickness is between about 400-800° A.

14. A method of forming split gate flash memory cell according to claim 4, wherein said gate poly silicon-3 mask is aligned to active area and then etched.

15. A method of forming a split gate flash memory cell according to claim 4, wherein said etching of floating gate poly-silicon-2 and select gate poly-silicon-1 are etched in a self-aligned manner.

16. A method of forming a split gate flash memory cell according to claim 4, wherein said three poly-silicon gates are vertically aligned with each other.

17. A method of forming split gate flash memory cell according to claim 4, wherein said source and drain regions are formed preferably by ion implantation doping.

18. A method of forming split gate flash memory cell according to claim 4, wherein said source and drain regions are formed by dopant deposition and diffusion.

19. A method of forming split gate flash memory cell according to claim 4, wherein formation of said electrical contacts comprise:
depositing contact metal on substrate;
forming self-aligned metal silicide on exposed silicon surfaces; and
removing un-reacted metal from non-silicon surfaces.

20. A method of forming split gate flash memory cell according to claim 4, wherein said electrical contact metal includes titanium, cobalt, nickel, and/or tantalum.

21. A method of forming split gate flash memory cell according to claim 20, wherein said contact metal is preferably titanium.

22. A method of forming electrical contact regions in split gate flash memory cell without select gate-to-drain bridging comprising:
forming a poly silicon-1 select gate stack on a silicon substrate, said stack including gate oxide, a gate poly silicon-1 layer, and first high temperature oxide (HTO) film;
etching said select gate stack;
forming sidewall silicon oxide spacers around said poly silicon-1 etched structure, depositing floating gate oxide, floating gate poly silicon-2, and oxide/nitride/oxide (ONO) films over said select gate poly silicon-1 etched structure;
depositing control gate poly silicon-3 and silicon-oxy-nitride (SiON) films over said poly-silicon-1/poly-silicon-2 composite structure;
selective anisotropic etching of said SiON and poly-silicon-3 films to stop on said ONO film;
forming two mirror image gate structures by two-step etching of said ONO and poly silicon-2 films to stop on said HTO film and then etching of said HTO and poly silicon-1 films to stop on said select gate oxide;
forming source and drain regions;
forming dielectric spacers in the drain contact region; and
forming electrical contacts on said silicon surfaces.

23. A method of forming electrical contacts in a split gate flash memory cell according to claim 22, wherein said dielectric spacer in said contact regions is formed from materials including, silicon dioxide, silicon nitride, silicon oxy-nitride, and/or nitrided oxide.

24. A method of forming electrical contacts in a split gate flash memory cell according to claim 23, wherein said dielectric spacer is preferably silicon dioxide.

25. A method of forming electrical contact regions in split gate flash memory cell according to claim 22, wherein formation of said electrical contacts comprise:
depositing contact metal on substrate;
forming self-aligned metal suicide on exposed silicon surfaces; and
removing un-reacted metal from non-silicon surfaces.

26. A method of forming electrical contacts in a split gate flash memory cell according to claim 25, wherein said electrical contacts are formed from metals to include titanium, cobalt, nickel, and/or tantalum.

27. A method of forming electrical contacts in a split gate flash memory cell according to claim 26, wherein said electrical contacts are formed preferably from titanium.

28. A triple-poly split gate flash memory cell comprising:
select gate oxide over silicon substrate;
select gate poly silicon-1 layer over said gate oxide;
first high temperature oxide insulating layer and spacers around said select gate;
floating gate oxide over said silicon substrate and surrounding said select gate;
floating gate poly silicon-2 over said select gate;
oxide-nitride-oxide (ONO) layer over said floating gate;
control gate poly silicon-3 over said ONO layer;
source and drain regions over said substrate and adjacent to said split gates;
second high temperature dielectric spacer around split gate structures; and
electrical contacts over source and drain regions.

29. A triple-poly split gate flash memory cell according to claim 28, wherein said second dielectric spacer is composed of silicon oxide, silicon nitride, silicon oxy-nitride, and/or nitrided oxide.

30. A triple-poly split gate flash memory cell according to claim 29, wherein the said second dielectric spacer is composed of preferably silicon dioxide.

31. A triple-poly split gate flash memory cell according to claim 28, wherein said electrical contacts are formed from metals composed of titanium, cobalt, nickel, and/or tantalum.

32. A triple-poly split gate flash memory cell according to claim 31, wherein the said electrical contact is composed of preferably titanium.
